(19) United States
(12) Patent Application Publication
(10) Pub. No.: US 2013/0309844 A1
(43) Pub. Date: Nov. 21, 2013

(54) LASER BEAM PROCESSING METHOD FOR WAFER

(71) Applicant: DISCO CORPORATION, Tokyo (JP)

(72) Inventor: Noboru TAKEDA, Tokyo (JP)

(73) Assignee: Disco Corporation, Tokyo (JP)

(21) Appl. No.: 13/888,552

(22) Filed: May 7, 2013

(30) Foreign Application Priority Data
May 15, 2012 (JP) 2012-111880

(51) Int. Cl. H01L 21/78

(52) U.S. Cl. CPC H01L 21/78
USPC 438/462

(57) ABSTRACT

A laser beam processing method for a wafer includes a first processed groove forming step in which a laser beam is radiated along a planned dividing line so that the overlapping rate of condensed beam spots is equal to or less than 95%, to thereby form a first laser beam processed groove. The laser beam processing method for a wafer further includes a second processed groove forming step in which a laser beam is radiated along the first laser beam processed groove in such a manner that the overlapping rate of condensed beam spots is equal to or more than 97%, to thereby form a second laser beam processed groove at a bottom portion of the first laser beam processed groove.

### BACKGROUND OF THE INVENTION

1. Field of the Invention

The present invention relates to a laser beam processing method for a wafer in which a surface of a wafer formed with a plurality of devices is irradiated with a laser beam, to perform ablation processing.

2. Description of the Related Art

Semiconductor devices such as memories, CPUs, etc. and optical devices such as LEDs (Light Emitting Diodes), etc. are manufactured by a method in which a laser beam is radiated by a laser beam processing apparatus along planned dividing lines of a wafer formed with semiconductor devices such as ICs (Integrated Circuits), LSIs (Large Scale Integrations), etc. or optical devices such as LEDs, etc., and the wafer is divided along the planned dividing lines.

In this laser beam processing method, the wafer has been divided into device chips by dividing the wafer through full-cutting with a cutting blade after formation of grooves by the laser beam, or through breaking up the wafer after formation of altered layers by the laser beam. A process has also been investigated in which grooves are formed deeply by a laser beam, and the wafer is finally divided. In this case, it has been found that when the flattening (degree of flatness) of the elliptic spot diameter of the laser beam is set high, a deep groove can be formed by a single run of irradiation with a laser beam and the desired processing can be performed efficiently (see, for example, Japanese Patent Laid-open No. 2007-275912).

### SUMMARY OF THE INVENTION

In the processing in which grooves are formed in a wafer by a laser beam, fused products of the wafer called debris may be deposited on both banks of the groove, depending on the amount of wafer removed. Both in the case where a deep groove is formed by a single run of laser beam scanning and in the case where the same position is irradiated with a laser beam a number of times to finally form a deep groove, large-height debris will be formed in substantially the same way. Such debris would cause plugging in suction of a picker (a component part for holding a chip by suction) for picking up the chips in the subsequent step, which has been a very serious problem.

Accordingly, it is an object of the present invention to provide a laser beam processing method for a wafer by which the fused products of wafer called debris can be restrained from being exposed to the surface of the wafer.

In accordance with an aspect of the present invention, there is provided a laser beam processing method for a wafer having a device in each of regions demarcated by a plurality of planned dividing lines formed in a grid pattern, the method including: a first processed groove forming step of radiating a pulsed laser beam along the planned dividing line in such a manner that the overlapping rate of condensed beam spots of the pulsed laser beam condensed onto the wafer is equal to or less than 95%, to thereby form a first laser beam processed groove; and a second processed groove forming step of radiating, after the first processed groove forming step is performed, the pulsed laser beam along the first laser beam processed groove in such a manner that the overlapping rate of condensed beam spots of the pulsed laser beam condensed onto the wafer is equal to or more than 97%, to thereby form a second laser beam processed groove at a bottom portion of the first laser beam processed groove, wherein the depth of the second laser beam processed groove is greater than the depth of the first laser beam processed groove, and debris generated in the second processed groove forming step is deposited inside the first laser beam processed groove so as not to protrude to a surface of the wafer.

Preferably, the condensed beam spot of the pulsed laser beam is elliptic in shape, the pulsed laser beam is radiated onto the wafer in the first processed groove forming step and the second processed groove forming step in such a manner that a major axis of the condensed beam spot lies along the planned dividing line, and the length of the major axis of the condensed beam spot in the second processed groove forming step is greater than the length of the major axis of the condensed beam spot in the first processed groove forming step.

In the laser beam processing method for a wafer according to the present invention, the pulsed laser beam is radiated at an overlapping rate of equal to or less than 95% to preliminarily form the first laser beam processed groove, after which the pulsed laser beam is radiated at an overlapping rate of equal to or more than 97% to form the deep second laser beam processed groove at a bottom portion of the first laser beam processed groove, and the wafer is divided into chips. In such processing, smaller-height debris are generated at the overlapping rate of equal to or less than 95%, while deep grooves can be formed at the overlapping rate of equal to or more than 97%, and the larger-height debris generated at the latter overlapping rate are accommodated inside the first laser beam processed groove, so as to be restrained from being exposed to the surface of the wafer. Therefore, in the case of processing the wafer comparatively deeply or fully cutting the wafer, the laser beam processing method for a wafer according to the present invention enables efficient processing to be achieved with a reduced number of laser beam scanning operations, while restraining the debris from being exposed to the wafer surface.

The above and other objects, features and advantages of the present invention and the manner of realizing them will become more apparent, and the invention itself will best be understood from a study of the following description and appended claims with reference to the attached drawings showing some preferred embodiment of the invention.

### BRIEF DESCRIPTION OF THE DRAWINGS

FIG. 1 is a perspective view of a configuration example of a laser beam processing apparatus by which to carry out the laser beam processing method for a wafer according to an embodiment of the present invention;

FIG. 2 is a perspective view of at least a wafer to be laser beam processed by the laser beam processing method for a wafer according to the embodiment;

FIG. 3 is a perspective view of the wafer to be laser beam processed by the laser beam processing method for a wafer according to the embodiment, in the state of being supported by an annular frame;

FIG. 4A is an illustration in a Y-axis direction of the configuration of a condenser of laser beam irradiation means wherein a condensed beam spot is elliptic in shape, of the laser beam processing apparatus according to the embodiment;

FIG. 4B is an illustration in an X-axis direction of the condenser of the laser beam irradiation means wherein the condensed beam spot is elliptic in shape, of the laser beam processing apparatus according to the embodiment;

FIG. 4C is a plan view of a condensed beam spot formed in an elliptic shape by the condenser of the laser beam irradiation means of the laser beam processing apparatus according to the embodiment;

FIG. 5A is an illustration in a Y-axis direction of the configuration of a condenser of laser beam irradiation means wherein a condensed beam spot is circular in shape, of the laser beam processing apparatus according to the embodiment;

FIG. 5B is an illustration in an X-axis direction of the configuration of the condenser of the laser beam irradiation means wherein the condensed beam spot is circular in shape, of the laser beam processing apparatus according to the embodiment;

FIG. 5C is a plan view of a condensed beam spot formed in a circular shape by the condenser of the laser beam irradiation means of the laser beam processing apparatus according to the embodiment;

FIG. 6A is a schematic illustration of a side sectional surface in a state where a first laser beam processed groove is formed, of the laser beam processing apparatus according to the embodiment;

FIG. 6B is a sectional view taken along line VIb-VIb of FIG. 6A;

FIG. 7A is a schematic illustration of a side sectional surface in a state where a second laser beam processed groove is formed, of the laser beam processing apparatus according to the embodiment;

FIG. 7B is a sectional view taken along line VIIb-VIIb of FIG. 7A;

FIG. 8 is a flow chart for the laser beam processing method for a wafer according to the embodiment; and

FIG. 9 is an illustration of the overlapping rate of condensed beam spots in the laser beam processing method for a wafer according to the embodiment.

### DETAILED DESCRIPTION OF THE PREFERRED EMBODIMENT

A preferred mode (embodiment) for carrying out the present invention will be described in detail below, referring to the drawings. The present invention is not to be restricted by the contents described in the following embodiment. In addition, the components described below include those which can come upon one skilled in the art and those which are substantially the same as the ones described below. Furthermore, the configurations described below can be combined with one another, as required. Besides, various omissions, replacements and modifications are possible without departure from the gist of the present invention.

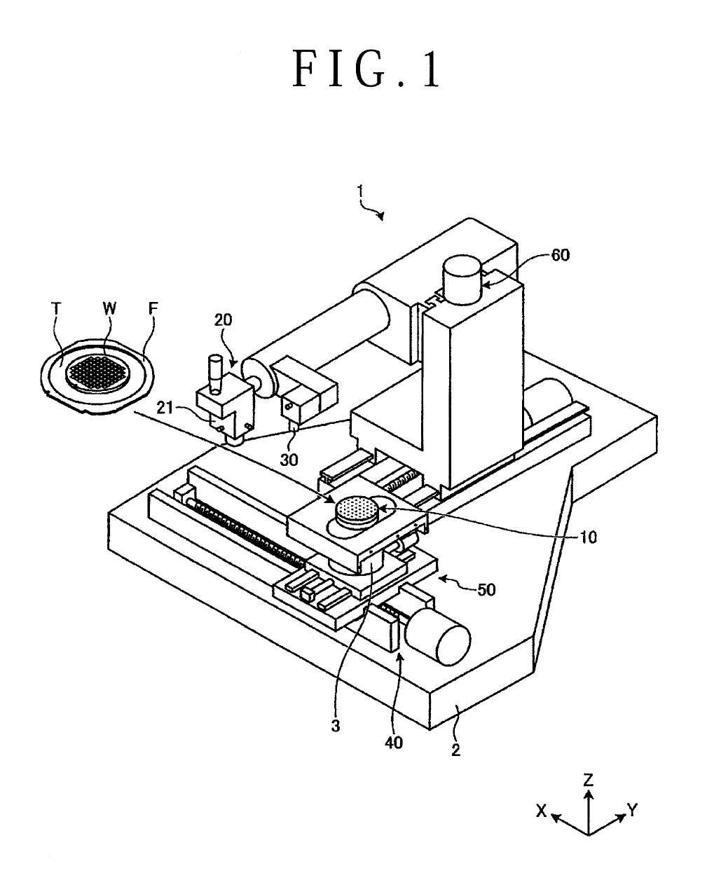

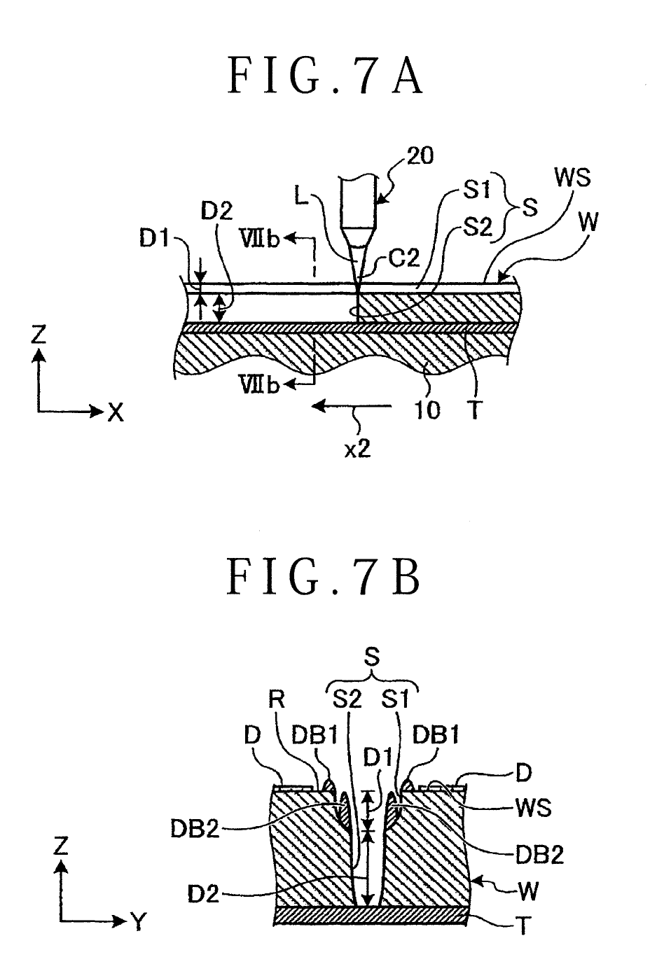

The laser beam processing method for a wafer W according to this embodiment is performed by a laser beam processing apparatus 1 shown in FIG. 1. The laser beam processing apparatus 1 is adapted to carry out a method in which a laser beam L of pulsed excitation (pulsed laser beam) is radiated onto the wafer W along planned dividing lines R while moving a chuck table 10 holding the wafer W thereon and laser beam irradiation means 20 relative to each other, whereby ablation processing is applied to the wafer W, to form laser beam processed grooves S (shown in FIGS. 7A and 7B) in the wafer W.

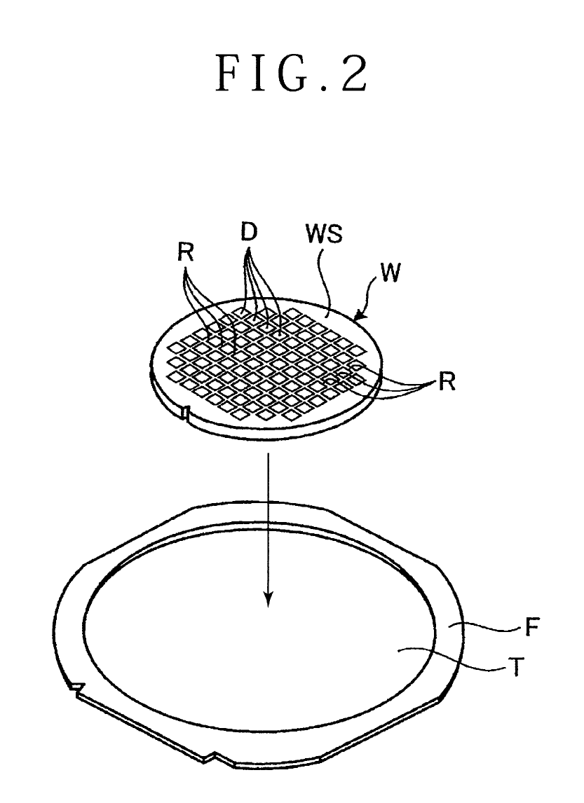

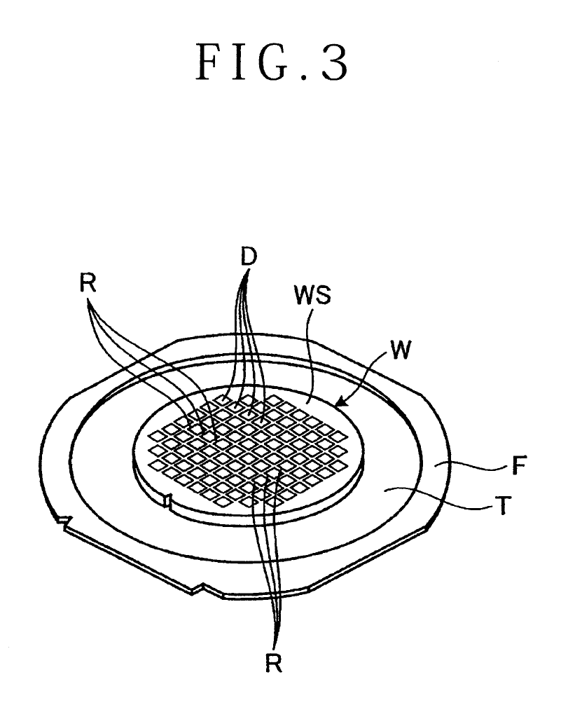

Here, the wafer W is an object of processing that is laser beam processed by the laser beam processing apparatus 1. In the present embodiment, the wafer W is a circular disk-shaped semiconductor wafer or optical device wafer of which the base material is silicon, sapphire, gallium or the like. As shown in FIGS. 2 and 3, the wafer W is formed at face-side surface WS with devices D in regions demarcated in a grid pattern by a plurality of planned dividing lines R. As shown in FIG. 3, a back-side surface on the side opposite to the face-side surface WS formed with the plurality of devices D, of the wafer W, is adhered to a pressure sensitive adhesive tape T, and an annular frame F is adhered to the pressure sensitive adhesive tape T adhered to the wafer W, whereby the wafer is fixed to the annular frame F.

As shown in FIG. 1, the laser beam processing apparatus 1 includes the chuck table 10, the laser beam irradiation means 20, image sensing means 30, and control means (not shown). Incidentally, the laser beam processing apparatus 1 includes: X-axis moving means 40 by which the chuck table 10 and the laser beam irradiation means 20 are put into relative movement along an X-axis direction; Y-axis moving means 50 by which the chuck table 10 and the laser beam irradiation means 20 are put into relative movement along a Y-axis direction; and Z-axis moving means 60 by which the chuck table 10 and the laser beam irradiation means 20 are put into relative movement along a Z-axis direction.

The chuck table 10 has a circular disk-like shape of which a surface portion is formed from porous ceramic or the like; it is connected to a vacuum suction source (not shown) through a vacuum suction passage (not shown), the wafer W before being laser beam processed is mounted thereon, and it holds the wafer W thereon by suction. Incidentally, the chuck table 10 can be detachably mounted to a table carriage 3 (shown in FIG. 1) provided on an apparatus main body 2 of the laser beam processing apparatus 1. The table carriage 3 can be moved in the X-axis direction by the X-axis moving means 40, can be moved in the Y-axis direction by the Y-axis moving means 50, and can be rotated about a center axis (parallel to the Z-axis) by a carriage driving source (not shown).

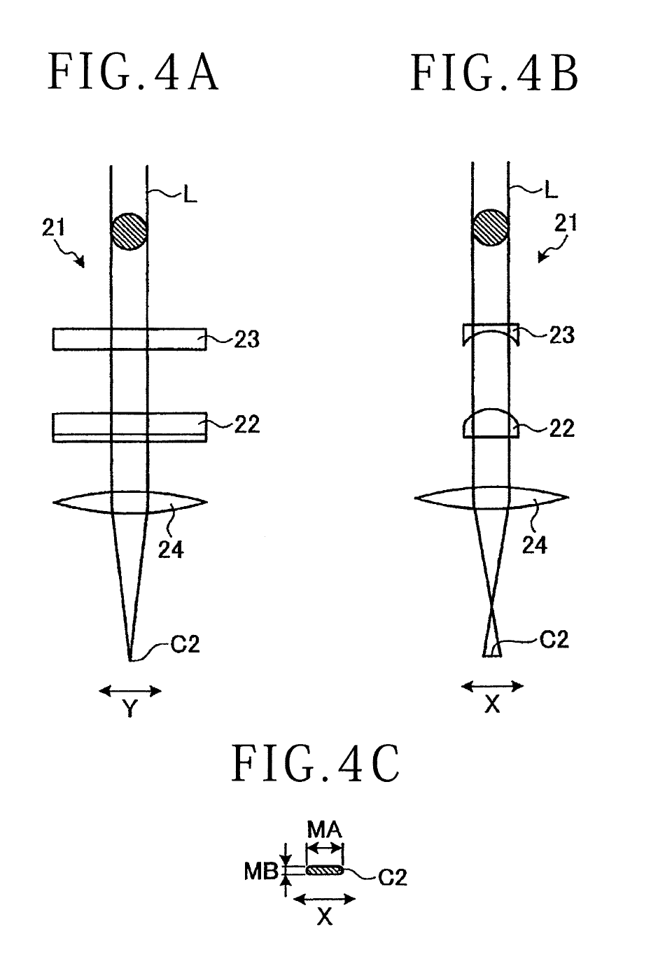

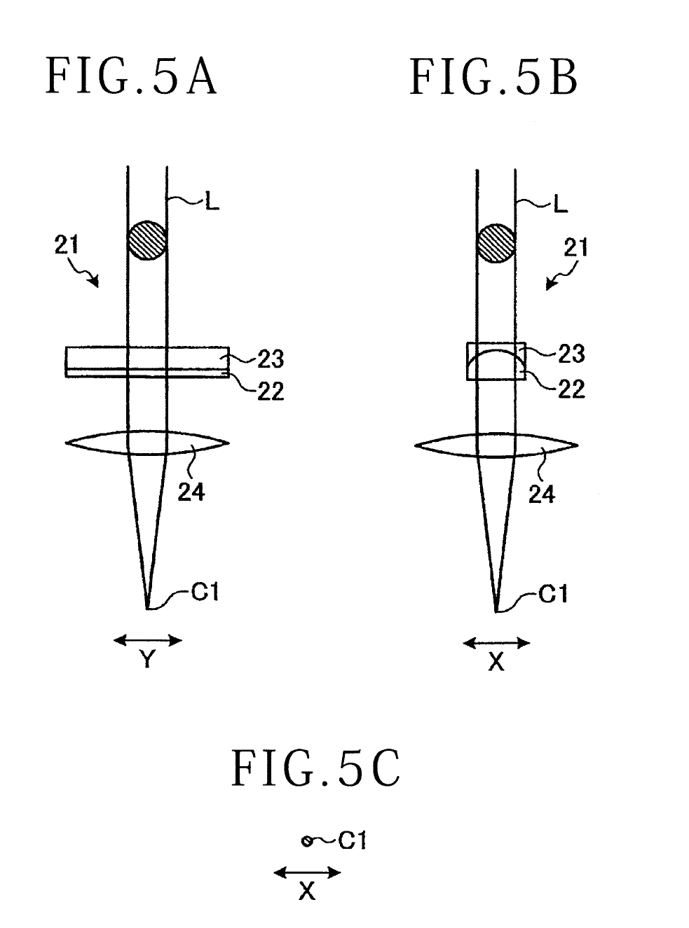

The laser beam irradiation means 20 is means by which the face-side surface WS of the wafer W is irradiated with a pulsed laser beam L (see FIGS. 4A to 5C). The laser beam irradiation means 20 can be moved in the Z-axis direction by the Z-axis moving means 60, relative to the wafer W held on the chuck table 10. The laser beam irradiation means 20 includes laser beam oscillation means (not shown), and a condenser 21 by which the pulsed laser beam L oscillated by the laser beam oscillation means is radiated to the face-side surface WS of the wafer W.

The laser beam oscillation means, by which the pulsed laser beam L with such a wavelength as to be absorbed into the wafer W is oscillated in a pulsed form, may be appropriately selected according to the kind of the wafer W, the processing mode and the like. For instance, a YAG laser oscillator, a YVO4 laser oscillator or the like can be used as the laser beam oscillation means. The laser beam oscillation means oscillates the laser beam L in a pulsed form with a repetition frequency of 10 kHz, for example. As shown in FIGS. 4A and 4B, the condenser 21 includes a first cylindrical lens 22 and a second cylindrical lens 23 through which the pulsed laser beam L oscillated by the laser beam oscillation means is passed, and a condenser lens 24 for condensing the pulsed laser beam L. The first cylindrical lens 22 is composed of a convex lens, while the second cylindrical lens 23 is composed of a concave lens.

In addition, the condenser 21 is so provided that the second cylindrical lens 23 can be moved, by a driving force of a motor (not shown), between a position at which the first cylindrical lens 22 and the second cylindrical lens 23 make contact with each other as shown in FIGS. 5A and 5B and a position at which the second cylindrical lens 23 is spaced from the first cylindrical lens 22 as shown in FIGS. 4A and 4B. When the first cylindrical lens 22 and the second cylindrical lens 23 are put in contact with each other as shown in FIGS. 5A and 5B, the condenser 21 forms a condensed beam spot C1 of the pulsed laser beam L in a circular shape as shown in FIG. 5C. On the other hand, when the first cylindrical lens 22 and the second cylindrical lens 23 are spaced from each other as shown in FIGS. 4A and 4B, the condenser 21 forms a condensed beam spot C2 of the pulsed laser beam L in an elliptic shape as shown in FIG. 4C.

The image sensing means 30 is for sensing an image of the face-side surface WS of the wafer W held on the chuck table 10. The image sensing means 30 is so provided that it can be moved in the Z-axis direction, relative to the wafer W held on the chuck table 10, together with the laser beam irradiation means 20 by the Z-axis moving means 60. The image sensing means 30 outputs to the control means the image of the face-side surface WS of the wafer W held on the chuck table 10.

The control means is for controlling the above-mentioned components of the laser beam processing apparatus 1 so as to cause the laser beam processing apparatus 1 to perform a processing operation on the wafer W. The control means causes the laser beam irradiation means 20 to radiate a pulsed laser beam L onto the face-side surface WS of the wafer W, so as to form a first laser beam processed grooves S1 and thereafter form a second laser beam processed grooves S2 at bottom portions of the first laser beam processed grooves S1, thereby forming the laser beam processed grooves S in the wafer W. Incidentally, the control means is composed mainly of a microprocessor (not shown) which includes an processor composed of a CPU or the like as well as a ROM, a RAM and the like. The control means is connected to display means (not shown) for displaying the status of the processing operation, and operating means (not shown) used at the time of registering information on the contents of processing and the like by the operator.

Now, the laser beam processing method for a wafer W according to the present embodiment will be described below. The laser beam processing method for a wafer W according to this embodiment is a method in which the laser beam L oscillated in a pulsed form is radiated along the planned dividing lines R formed on the face-side surface WS of the wafer W, to perform ablation processing, thereby forming the laser beam processed grooves S. The laser beam processing method for a wafer W includes at least a first processed groove forming step and a second processed groove forming step.

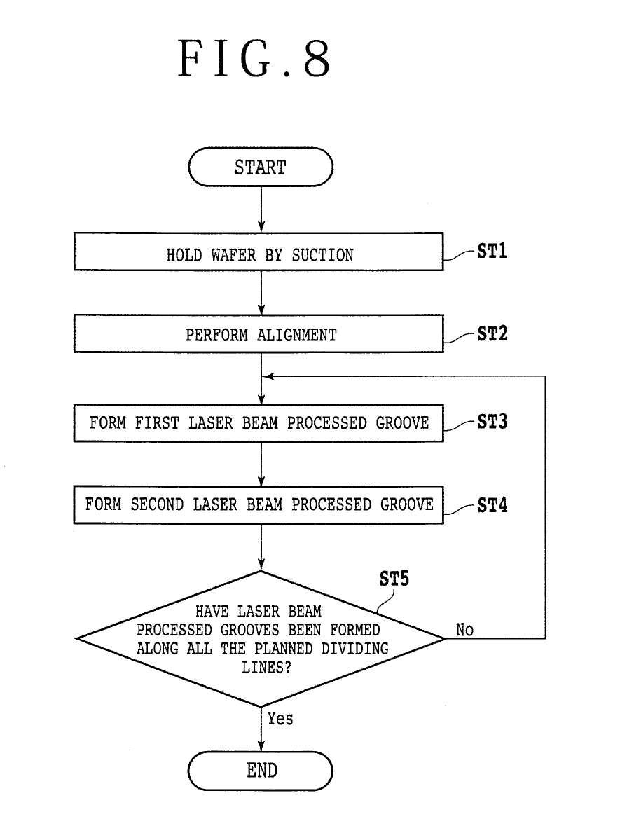

In the laser beam processing method for a wafer W, information on the contents of processing is registered in the control means by the operator, and the laser beam processing apparatus 1 starts performing a processing operation when a processing operation starting instruction is supplied from the operator. In the processing operation, the wafer W adhered to the annular frame F through the pressure sensitive adhesive tape T is mounted on the chuck table 10, then the control means effects suction holding of the wafer W onto the chuck table 10 in step ST1 in FIG. 8, and the control proceeds to step ST2.

Then, the control means effects movement of the chuck table 10 through the X-axis moving means 40 and the Y-axis moving means 50, thereby causing the wafer W held on the chuck table 10 to be positioned on the lower side of the image sensing means 30, and causes the image sensing means 30 to sense an image. The image sensing means 30 outputs the thus sensed image to the control means. Then, the control means carries out image processing such as pattern matching for matching the planned dividing line R on the wafer W held on the chuck table 10 and the condenser 21 of the laser beam irradiation means 20, thereby to perform alignment of the laser beam irradiation means 20, and the control proceeds to step ST3.

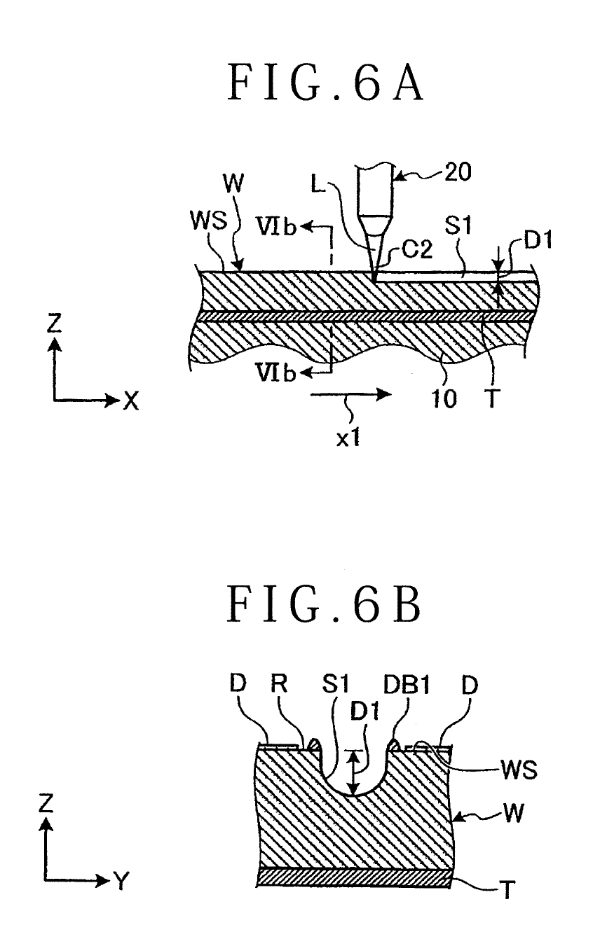

Next, in step ST3, the control means causes the pulsed laser beam L to be radiated along the planned dividing line R while moving the chuck table 10 in the direction of arrow X1 (shown in FIG. 6A) by the X-axis moving means 40, in such a manner that the overlapping rate of elliptic condensed beam spots C2 of the pulsed laser beam L condensed onto the wafer W is in the range from 50% to 95%, inclusive. The control means forms the first laser beam processed groove S1 (constituting the laser beam processed groove S), as shown in FIGS. 6A and 6B. The first laser beam processed groove S1 is formed in a comparatively shallow form, and debris DB1 (represented by densely arranged parallel oblique lines in FIG. 6B) composed of fused products of the wafer W generated upon the formation of the first laser beam processed groove S1 are formed as small-height projections at both banks of the first laser beam processed groove S1. Incidentally, step ST3 corresponds to the first processed groove forming step, after which the control proceeds to step ST4.

Subsequently, in step ST4, the control means causes the pulsed laser beam L to be radiated along the first laser beam processed groove S1 while moving the chuck table 10 in the direction of arrow X2 (shown in FIG. 7A) opposite to arrow X1 by the X-axis moving means 40, in such a manner that the overlapping rate of the condensed beam spot C2 of the pulsed laser beam L condensed onto the wafer W is equal to or more than 97% and less than 100%. The control means forms the second laser beam processed groove S2 (constituting the laser beam processed groove S) at a bottom portion of the first laser beam processed groove S1, as shown in FIGS. 7A and 7B.

Incidentally, since the overlapping rate in step ST4 is higher than the overlapping rate in step ST3, the depth D2 of the second laser beam processed groove S2 is greater than the depth D1 of the first laser beam processed groove S1, as shown in FIGS. 7A and 7B. In addition, the debris DB2 (represented by densely arranged parallel oblique lines in FIG. 7B) composed of fused products of the wafer W generated in step ST4 are formed as projections at both banks of the second laser beam processed groove S2, and are deposited inside the first laser beam processed groove S1; therefore, the debris DB2 do not protrude to the face-side surface WS of the wafer W. Besides, in the present embodiment, the second laser beam processed grooves S2 pierce through the wafer W. Incidentally, step ST4 corresponds to the second processed groove forming step, and the debris DB1 and DB2 are omitted in FIGS. 6A and 7A.

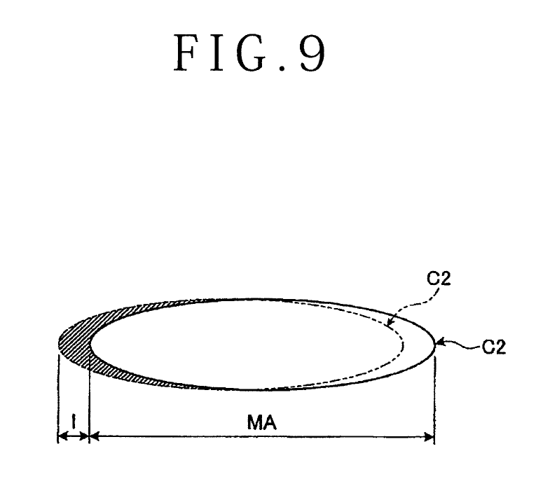

In step ST3 and step ST4 in the present embodiment, the control means causes the cylindrical lenses 22 and 23 of the condenser 21 in the laser beam irradiation means 20 to be spaced from each other. The pulsed laser beam L is so radiated that the condensed beam spot C2 is elliptic in shape, and the major (longitudinal) axis of the condensed beam spot C2 lies along the planned dividing line R and the X-axis, as shown in FIG. 4C. Besides, the control means causes the laser beam irradiation means 20 to oscillates the laser beam L in a pulsed form, whereby the condensed beam spots C2 of the pulsed laser beam L condensed onto the face-side surface WS of the wafer W moved by the X-axis moving means 40 are only partly overlapped with each other (and are not overlapped at the other parts), as represented by solid line and two-dot chain line in FIG. 9.

The overlapping rate in the present invention can be expressed by the following Formula 1:

Overlapping rate (%)=((MA−1)/MA)×100 Formula 1

where MA is the diameter in the major (longitudinal) axis of the condensed beam spot C2 of the laser beam L oscillated in a pulsed form and condensed onto the face-side surface WS of the wafer W, and 1 is the length in the central major (longitudinal) axis of the non-overlapping part (represented by parallel oblique lines in FIG. 9) of the condensed beam spots C2 adjacent to each other.

Besides, in step ST3 and step ST4 in the present embodiment, the laser beam irradiation means 20 radiates the pulsed laser beam L with the same frequency and the same repetition frequency so that the pulsed laser beam L is condensed into elliptic condensed beam spots C2 with the same shape on the face-side surface WS of the wafer W. For instance, the diameter MA (shown in FIG. 4C) in the major (longitudinal) axis of the condensed beam spot C2 is 100 to 800 μm and the diameter MB (shown in FIG. 4C) in the minor axis (short side) of the condensed beam spot C2 is 5 to 10 μm. Furthermore, in the present embodiment, the moving velocity of the chuck table 10 in step ST4 is lower than the moving velocity of the chuck table 10 in step ST3.

After step ST4, the control proceeds to step ST5. In step ST5, the control means determine whether or not the first laser beam processed grooves S1 and the second laser beam processed grooves S2 have been formed along all the planned dividing lines R, namely, whether or not the laser beam processed grooves S have been formed along all the planned dividing lines R. When it is determined that the first laser beam processed grooves S1 and the second laser beam processed grooves S2 have not been formed along all the planned dividing lines R, the control returns to step ST3.

Incidentally, when the first laser beam processed grooves S1 and the second laser beam processed grooves S2 have been formed along all the planned dividing lines R, the first laser beam processed grooves S1 and the second laser beam processed grooves S2 formed along all the planned dividing lines R have pierced through the wafer W, and the wafer W has been divided into chips each of which includes the device D. When it is determined that the first laser beam processed grooves S1 and the second laser beam processed grooves S2 have been formed along all the planned dividing lines R, the control means stops the laser beam processing by the laser beam irradiation means 20, and retracts the chuck table 10 from the position on the lower side of the laser beam irradiation means 20 by the X-axis moving means 40. The wafer W having undergone the laser beam processing is detached from the chuck table 10. When a wafer W before being laser beam processed is mounted on the chuck table 10, the control means causes the laser beam processing to be applied to the wafer W in the same manner as in the above-described process.

As above-mentioned, according to the laser beam processing method for a wafer W according to the present embodiment, irradiation with the pulsed laser beam L is conducted at an overlapping rate of equal to or less than 95%, whereby the shallower first laser beam processed grooves S1 are preliminarily formed, after which the deeper second laser beam processed grooves S2 are formed at bottom portions of the first laser beam processed grooves S1 at an overlapping rate of equal to or more than 97%. In such processing, small-height debris DB1 are generated at the overlapping rate of equal to or less than 95%, whereas the deeper grooves can be formed at the overlapping rate of equal to or more than 97%, with the result that the large-height debris DB2 thus generated are accommodated inside the first laser beam processed grooves S1. Therefore, the large-height debris DB2 generated upon the formation of the second laser beam processed grooves S2 can be restrained from being exposed to the face-side surface WS of the wafer W. Accordingly, in the case of processing the wafer W comparatively deeply or fully cutting the wafer W, the laser beam processing method for a wafer W according to the present embodiment enables efficient processing to be achieved with a reduced number of times of scanning of the laser beam L, while restraining the debris DB2 from being exposed to the face-side surface WS of the wafer W.

In addition, according to the laser beam processing method for a wafer W according to the present embodiment, the overlapping rate in step ST3 is set to be equal to or more than 50%. Therefore, the first laser beam processed grooves S1 can be formed in a uniform width, so that the second laser beam processed grooves S2 can be formed assuredly at bottom portions of the first laser beam processed grooves S1. Besides, the overlapping rate in step ST4 is set to be less than 100%. Therefore, the second laser beam processed grooves S2 can be formed assuredly at the bottom portions of the first laser beam processed grooves S1.

In the embodiment described above, after the first laser beam processed groove S1 is formed along a single planned dividing line R, the second laser beam processed groove S2 is formed at the bottom portion of the first laser beam processed groove S1. In the present invention, however, another configuration may be adopted wherein after the first laser beam processed grooves S1 are formed along all the planned dividing lines R, the second laser beam processed grooves S2 are formed at the bottom portions of the first laser beam processed grooves S1.

In the above-described embodiment, the second laser beam processed groove S2 is formed in step ST4 after the first laser beam processed groove S1 is formed in step ST3. In the present invention, however, another configuration may be adopted wherein at least one laser beam processed groove is further formed at a bottom portion of the second laser beam processed groove S2. In this case, the overlapping rate may be enhanced at the time of forming a latter laser beam processed groove, or the overlapping rate in forming the latter laser beam processed groove may be equal to the overlapping rate in forming the second laser beam processed groove S2. In addition, in the present invention, the second laser beam processed groove S2 may be formed after the first laser beam processed groove S1 is formed multiple times.

In the embodiment described above, the condensed beam spot C2 in step ST3 is the same in shape as the condensed beam spot C2 in step ST4. In the present invention, however, the length in the major axis of the condensed beam spot C2 of the laser beam L may be greater in step ST4 than in step ST3.

While the overlapping rate in step ST3 has been equal to or less than 95% and the overlapping rate in step ST4 has been equal to or more than 97% in the embodiment described above, this is not restrictive of the present invention. In short, in the present invention, it suffices that the overlapping rate in step ST4 is set to be higher than the overlapping rate in step ST3, to thereby ensure that the first laser beam processed grooves S1 are shallower, whereas the second laser beam processed grooves S2 are deeper than the first laser beam processed grooves S1, and the debris DB2 generated upon the formation of the second laser beam processed grooves S2 are deposited inside the first laser beam processed grooves S1. In other words, it suffices in the present invention that steps are provided such that a lower overlapping rate is previously adopted to form the first laser beam processed groove S1 in a comparatively shallower form, and thereafter a higher overlapping rate is adopted to form the second laser beam processed groove S2 in a comparatively deeper form.

Besides, while the second laser beam processed grooves S2 have been so formed as to pierce through the wafer W in the above-described embodiment, the second laser beam processed grooves S2 in the present invention may not necessarily pierce through the wafer W. The present invention is not restricted to the above-described embodiment, and various modifications are possible within the scope of the gist of the invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser beam processing method for a wafer having a device in each of regions demarcated by a plurality of planned dividing lines formed in a grid pattern, the method comprising:
a first processed groove forming step of radiating a pulsed laser beam along the planned dividing line in such a manner that the overlapping rate of condensed beam spots of the pulsed laser beam condensed onto the wafer is equal to or less than 95%, to thereby form a first laser beam processed groove; and
a second processed groove forming step of radiating, after the first processed groove forming step is performed, the pulsed laser beam along the first laser beam processed groove in such a manner that the overlapping rate of condensed beam spots of the pulsed laser beam condensed onto the wafer is equal to or more than 97%, to thereby form a second laser beam processed groove at a bottom portion of the first laser beam processed groove,
wherein the depth of the second laser beam processed groove is greater than the depth of the first laser beam processed groove, and debris generated in the second processed groove forming step is deposited inside the first laser beam processed groove so as not to protrude to a surface of the wafer.

2. The laser beam processing method for a wafer according to claim 1,
wherein the condensed beam spot of the pulsed laser beam is elliptic in shape,
the pulsed laser beam is radiated onto the wafer in the first processed groove forming step and the second processed groove forming step in such a manner that a major axis of the condensed beam spot lies along the planned dividing line, and
the length of the major axis of the condensed beam spot in the second processed groove forming step is greater than the length of the major axis of the condensed beam spot in the first processed groove forming step.
